(19) United States
(12) Patent Application Publication
(10) Pub. No.: US 2009/0315563 A1
(43) Pub. Date: Dec. 24, 2009

(54) Detection of Resistivity of Offshore Seismic Structures Mainly Using Vertical Magnetic Component of Earth's Naturally Varying Electromagnetic Field

(76) Inventors: Anthony C. L. Fox, Toronto (CA); Olexandr Ingerov, North York (CA)

Correspondence Address: HARNESS, DICKEY & PIERCE, P.L.C., P.O. BOX 828, BLOOMFIELD HILLS, MI, 48303, US

(21) Appl. No.: 12/087,702

(22) PCT Filed: Jan. 13, 2006
(86) PCT No.: PCT/CA2006/000042

§ 371 Date: Jan. 22, 2009

(51) Int. Cl. G01V 3/08; G01R 27/08

(52) U.S. Cl. 324/345; 324/705

(57) ABSTRACT

The invention measures the vertical component Hz of a magnetic field arising from natural sources (MT) simultaneously at a plurality of points (70) on the sea floor to determine places having a non-zero vertical component Hz indicative of an edge of a resistive body (structure) (40), in order to determine whether or not a sub-bottom geologic structure (20), known from marine seismic measurements, exhibits a resistivity contrast with the surrounding rocks, a positive contrast being interpreted as indicating hydrocarbon charge within the structure.

### FIELD OF THE INVENTION

This invention relates to a method and apparatus for determining the nature of submarine and subterranean reservoirs. More particularly, the invention is concerned with determining whether a reservoir, or more specifically, a geological structure, whose approximate geometry and location are known from the seismic technique, contains hydrocarbons or water; and more particularly, for offshore sub-bottom structures.

### BACKGROUND OF THE INVENTION

Since 1998 there has been growing use of EM (electromagnetic) geophysical techniques by oil companies, mainly to determine the electrical resisitivity of offshore geological structures (possible hydrocarbon traps) already discovered with the marine seismic technique. The seismic technique is usually capable of revealing the geological layering and structure in considerable detail, but it cannot reliably distinguish between oil and water in the traps.

Major multinational oil companies (usually called “the majors”) are primarily interested in offshore exploration, mainly in deep water. Issues associated with direct ownership of onshore hydrocarbon resources have resulted in such resources now being mainly controlled by national oil companies. The majors also require very large discoveries (hundreds of millions of barrels or more) because of the scale of their operations. The most likely place to look for such giant hydrocarbon accumulations is offshore. Most of the leading edge expertise for offshore hydrocarbon exploration is concentrated in the majors and their associated suppliers, although some national oil companies have significant offshore operations and expertise.

For these reasons, the majors have increasingly focused on offshore exploration, moving step by step into ever deeper waters. It is now possible (and not uncommon) to drill in water depths of ˜2000 m or even more.

Deep water drilling is, however, very expensive, costing typically from US$20 Million to US$50 Million per well (or even more). These are significant expenditures even for large oil companies.

Hence the interest of oil companies in techniques which may mitigate offshore drilling risk.

Hydrocarbons are electrically resistive, so hydrocarbon-charged marine sediments (sedimentary rocks) have a significantly higher electrical resistivity (˜100 ohm-m to ˜250 ohm-m) than a typical geologic section of “fresh” marine sediments (typically 1 to 3 ohm-m), where the ohm-m is the unit of electrical resistivity.

Because of the different physics of the behaviour of EM waves in earth materials, compared to seismic waves, the EM techniques by themselves are generally considered to have insufficient vertical resolution to be useful as primary hydrocarbon exploration tools. Therefore, the majors are mainly interested in using marine EM techniques to sense whether a favourable-looking offshore geological structure already discovered by the seismic technique (henceforth called a “structure” or “seismic structure” or “discovered seismic structure”) has significantly higher resistivity than the surrounding rocks; if so, the structure is interpreted as being charged with hydrocarbons. If, on the other hand, the structure exhibits little or no resistivity contrast with the more conductive surrounding rocks, then it is interpreted as being “wet” i.e., as containing only or mainly relatively conductive formation brines.

As indicated above, the motivation is to avoid the very high cost of drilling offshore unproductive wells or so-called “dry holes”.

Previously, the only successful technique for detecting the resistivity of offshore structures was considered to be marine controlled source EM (MCSEM), developed by the state oil company of Norway (Statoil), which is the subject of U.S. Pat. No. 6,628,119 B1 as well as later patent applications as mentioned on the web site www.emgs.no

The holders of U.S. Pat. No. 6,628,119 B1 use the trade name “Sea Bed Logging” for the MCSEM technique.

In their first field tests (proof of concept) of the MCSEM technique, the holders of the above-mentioned patent applied existing technology in a new way, for a new objective. The existing technology comprised marine controlled source EM equipment and marine MT (magnetotelluric) equipment already developed by academic researchers for general geological or structural investigations. The MCSEM equipment is divided into two portions: the “transmitter” or controlled source (the man-made source of the EM field used to illuminate the target) and the companion “receiver” equipment used for measuring two orthogonal/horizontal components of the electric field. In addition to existing MCSEM receiver equipment, the first MCSEM tests used as receivers already existing marine MT (MMT) receiver equipment, since, as indicated below, that equipment included the capability of measuring 2 orthogonal/horizontal electric field components.

The MCSEM and MMT receiver units include synchronization using suitable stable onboard quartz oscillators. After data acquisition, the receiver units (upon receipt of an acoustic command from the survey vessel) initiate a “burn sequence” to release, an attached anchor (usually an expendable concrete prism); attached buoyancy elements then cause the receiver unit to float to the surface, where it is located by radio beacons and other means, recovered onto the survey vessel, and the data extracted for subsequent post-processing.

The above-mentioned MT technique is a different EM technique, invented in the early 1950s, used mainly onshore, mainly for large-scale geological structural investigations, and for hydrocarbon exploration mainly in regions where seismic data quality is unsatisfactory, usually because of the presence of one or more dense rock layers in the geological section. Onshore MT was adapted for offshore oil exploration (“Marine MT” or MMT) starting approx. in the early 1990s, and initially did not use any new equipment—it simply used existing marine MT equipment developed earlier by oceanographers for general sub-bottom geological investigations. The tensor MT/MMT technique requires measurement of two orthogonal horizontal components of the natural electric field and two orthogonal components of the natural magnetic field, measured in the same directions as the electric field components. The resulting data can be processed to yield a resistivity vs. depth image of the subsurface. “Tensor” means that the magnetic and electric field components are measured simultaneously in two orthogonal horizontal directions. Although the MCSEM tests were able to use the existing MMT equipment, only the electric field components were required to be measured by the MCSEM technique, not the magnetic field components.

The term “controlled source EM” means that the source of the EM field used to investigate the target is an artificial, or man-made source. This is in contrast to the Magnetotelluric (MT) technique, which is a “passive” or “natural source” technique, which uses variations of the earth's natural EM field mainly to obtain a resistivity vs. depth image of the earth below the recording unit.

In MCSEM, the controlled source is a towed horizontal dipole (towed at an altitude of ˜30 m above the sea floor). Lucid expositions of the MCSEM technique have been provided in various publications and presentations, for example (Farrelly et al., 2004) and (Ellingsrud et al., 2002). A low-frequency (˜1 Hz) alternating electric current of several hundred amperes or more is forced to flow in the dipole. This radiates an EM field (the “primary field”) into the seawater and downwards into the sea floor. The dipole is towed by a suitable vessel along a suitable pre-planned pattern of tow lines during a period of several days. The “secondary field” (the signal arising from interaction of the primary field with the structure under investigation) is measured by an array of specialized seafloor receiver units, which typically measure two orthogonal horizontal components of the electric field. After data processing, the results are displayed as normalized Magnitude vs. Offset (MVO) profiles. Anomalously high values (compared to off-structure background values) are interpreted as being due to hydrocarbon charge in the structure under investigation. Normalized anomalies may be as much as 3 or 4 times background. FIG. 5 in (Farrelly et al., 2004) shows an anomaly approx. 4 times background (300%) measured over the giant Troll Field in the North Sea.

It is worth noting that the electric voltage differences measured in the MCSEM (and MMT) techniques are very small in absolute terms (comparable to those measured with the MT and MMT technique), even though in the MCSEM technique the normalized anomalies may be as much as 2 to 4 times background. Carefully-designed, low-noise equipment is required in all cases.

The previously mentioned MT geophysical technique uses naturally occurring variations in the earth's electromagnetic field as its source of energy. The electric field components are also referred to as telluric fields (based on a Latin name for the Earth, Tellus). The name of the MT technique implies its basic procedure, that is, simultaneous measurement of both magnetic and electric field components. Without going into detail, suffice to state that earth resistivity below the measuring location is derived from the ratio of the electric and magnetic field components; and that measurement of both components is required in order to permit calculation of resistivity using the natural field variations. Note also that practitioners of the MCSEM technique have found that measurement of the horizontal components of the magnetic field (at a smaller number of locations compared to those where the electric field is measured) is desirable; in other words, an MMT measurement is made in order to provide a “background model” of the sub-bottom resistivity, which permits a more reliable interpretation of the MCSEM data.

It has heretofore been thought that only the MCSEM technique can reliably determine the resistivity of offshore seismic structures, because the MMT technique is considered to be too insensitive to relatively thin resistive bodies (such as the typical offshore hydrocarbon deposit) and that anomalies arising from the natural field are too small to be detected reliably.

FIG. 1 (from Um et al., 2005) shows a typical resistivity model (in cross-section) of a hydrocarbon-charged offshore geological structure 20. The hydrocarbon-charged structure is an anticline with long axis in and out of the page. The long axis is considered to be “infinitely” long; this type of model is called a 2-D model, in which the properties vary in only 2 dimensions. Such models are satisfactory if the long axis is of the order of >3× the length of the short axis. The anticline is approx. 4 km wide, with a vertical relief of 500 m. The hydrocarbon-charged layer is 100 m thick, with a resistivity of 100 ohm-m. The background rocks have a resistivity of 0.7 ohm-m. This is comparable to the Troll Field studied in (Farrelly et al 2004) which has a hydrocarbon-charged section approx. 10 km wide, up to 300 m thick, with resistivity up to 250 ohm-m, in background rocks of 1 ohm-m to 2.5 ohm-m.

FIG. 2 (which displays a model of the Troll Field, using the parameters provided in (Farrelly et al., 2004)) was used by the inventors of the present invention to estimate and study the anomalous response of a relevant sub-bottom target to the natural-source MT technique. The advantage of using a model of the Troll Field is that it is a real example, and also it permits a comparison of the MCSEM responses reported in (Farrelly et al., 2004) with those expected by using the present invention. In FIG. 2, both vertical (depth) and horizontal (distance) scales are in meters (m). The virtual measurement locations are a sequence of small black circles 30 (numbered 2-66) on the sea floor. In this model, the hydrocarbon-charged layer 40 is 100 m thick on the left side, 300 m thick elsewhere, approximates a horizontal rectangular prism in cross-section, has a resistivity of 200 ohm-m, and is 9.8 km wide. As in FIG. 1, the long axis of the sub-bottom structure is into/out of the page, and is treated as being as “infinite” in length—an acceptable approximation.

The background rocks have resistivity of 2 ohm-m. The sea water is 340 m deep, and has a resisitivity of 0.25 ohm-m.

FIGS. 3 to 6 are graphs of the results of the modelling study based on the model of FIG. 2 showing, period (vertical axis) versus distance (horizontal axis) and showing respectively TE resistivity, TE phase, TM resistivity and TM phase. The results of the modelling study are those that would be obtained by making actual measurements over a sub-bottom target as shown in FIG. 2. FIG. 3 shows the resistivity that would be measured (by the array of seafloor receivers) in a direction parallel to the long axis of the structure (called “TE” direction). FIG. 4 shows the corresponding TE phase. FIG. 5 shows the resistivity that would be measured (by the array of seafloor receivers) in a direction orthogonal to the long axis of the structure (called “TM” direction). FIG. 6 shows the corresponding TM phase.

In these figures, the vertical axis is the logarithm (base 10) of the period of the EM wave, and the horizontal axis is distance in meters (m), as in FIG. 2.

It can be observed in FIGS. 3 and 5 that the anomalous response in resistivity is approx. 15%. FIGS. 4 and 6 show that the anomalous response in phase is approx. 4 degrees, or approx. 10%. Note that the resistivity and phase parameters illustrated in these figures are computed from the measurement made with only horizontal magnetic and electric fields.

The magnitude of the anomalous natural-field (MT) response from the FIG. 2 model may be compared to the MCSEM anomalies described in (Farrelly et al., 2004) which are as much as 300% (4 times background). Note however, that (Farrelly et al., 2004) also indicate that much smaller anomalies are reliable, at offset distances as great as 10 km. Their FIG. 5 and related discussion indicates that normalized anomaly magnitudes as small as 0.05 (5%) are considered reliable. In other words, the small anomalies are significant when observed in conjunction with a larger anomaly, especially when the entire pattern exhibits a consistent spatial variation and is in meaningful registration with the known target under investigation.

FIGS. 3 to 6 of the present document indicate that the largest anomalous magnitudes in resistivity and phase that can be expected by using the 4-component marine MT technique are considerably smaller than the largest anomalous magnitudes that can be detected using the MCSEM technique, and are in fact comparable to the smallest anomalous magnitudes considered reliable in the MCSEM technique.

Since the naturally-occurring (MT) horizontal electric and magnetic fields are relatively strong and relatively insensitive to errors from true horizontality, and since the marine environment is very quiet compared to the land environment (no man-made EM noise), the results of the modelling exercise and comparison above indicate that a relatively dense net of 4-component MMT soundings with good data quality (1% in resistivity, 1 degree in phase) coupled with appropriate pattern-extraction techniques, might be able to detect the positive resistivity anomaly associated with a hydrocarbon-charged offshore structure such as the Troll Field, contrary to prevailing assumptions. Note, however, in the real measurement, there is unavoidable noise from various sources, and this acts to mask small anomalies; and not all structures are as big as the Troll Field. Also, the cost for MMT measurement points is not significantly less than for MCSEM measurement points, since both are dominated by the operating cost for the required vessel. For these reasons, given the existence of the MCSEM technique, and given that a 4-component MCSEM receiver can be, and is used as an MMT receiver, there is little motivation to use MMT alone as an alternative to MCSEM for the objective described herein.

The vessels used in the CSEM technique are relatively costly (approx. US$70,000 per day), and a single marine MT±CSEM measurement point costs approx. US$7,000.

It would therefore be of interest to have a less costly marine EM technique which can answer the fundamental questions of interest: does the discovered offshore seismic structure display a resistivity contrast with the surrounding rocks; and, secondarily, what is the sign (polarity) of the anomaly?

The present invention presents precisely such an alternative.

### SUMMARY OF THE INVENTION

The invention involves measuring simultaneously at a relatively large number of seafloor points, the vertical component Hz, of the natural MT field. The measurements are taken along suitably positioned profile(s) which cross the structure to be studied. The “production” measurements are normalized to measurements of Hz made at an off-structure reference location; among other things this removes the effect of temporal variations of the source field. The purpose of the invention is to determine as economically as possible the existence, boundaries and epicentre of a sub-bottom resistivity anomaly that is associated with hydrocarbon charge in an offshore geologic structure already discovered by the marine seismic technique. Several sequential deployments of the measuring equipment can be made, all normalized to the same reference location.

Note that in order to normalize the measurements, it is necessary to measure Hz simultaneously at least at one reference (normalizing) location and one “production” location. The natural field amplitude and phase (at a particularly frequency) cannot be predicted at any particular moment in time; however, the characteristics of the natural field are such that the primary field is instantaneously the same everywhere over a distance of a few km at high frequencies, even hundreds of km at low frequencies. So, normalizing to a fixed reference station removes the effect of quasi-random amplitude and phase variations (time dependence) of the primary field, permits the use of measurements made at different times, as long as they are normalized to the same reference location; and also removes the background response at the reference location, permitting clearer recognition of the anomalous response. Making the “production” measurement at a number of points simultaneously improves the productivity of the technique as well as providing other advantages mentioned elsewhere.

This invention also recognizes that the addition of a vertical magnetic field measurement (as described herein) to standard 4-component MMT measurements (whether incorporated into the same apparatus, or measured nearby with an autonomous apparatus) provides additional diagnostic information that can increase the reliability of the relatively small magnitude anomalies expected when using only the horizontal components of the natural-field source. This is because the anomalies associated with the vertical field may be as much as 5× to 10× expected background, that is, of magnitude similar to, or even greater magnitude than the anomalies observed with the MCSEM technique.

Note that it is to be understood that all measurements at a set or subset of measuring points are made simultaneously, by means of suitable onboard synchronization devices of known types, which are readily available. Also, the location of the measuring devices, in descent, ascent, or while emplaced on the seafloor, is known such as by use of existing acoustic pinger technology. Also, the well-known remote reference noise-reduction technique of MT (Gamble et al., 1979) may be used as permitted and as adapted to the approach herein.

A further aspect of the present invention involves measuring at a considerably smaller number of locations, preferably, but not necessarily exactly at the same points where Hz is measured, the horizontal components Hx and Hy of the magnetic field arising from the natural source, in order to determine unambiguously the “sign” of the resistivity anomaly.

A further aspect of the present invention involves measuring at a subset of points, in addition to three components of the magnetic field, two horizontal components of the electric field, preferably in the same directions as the two horizontal components of the magnetic field, at the same or nearby locations, and using the additional information from the electric field to calculate resistivity, and thus to develop a model of the background resistivity structure of the sub-bottom rocks.

According to a further aspect of the present invention, an Hz sensor apparatus is provided which has a base, a support extending upwardly from the base for swingably supporting an Hz sensor to hang downwardly in a pendulum like manner in a deployed configuration. Recording and control electronics are mounted to the base and communicate with the Hz sensor. A power source is connected to the recording and control electronics for providing power thereto.

The Hz sensor may be mounted in a non-magnetic pressure vessel for protecting the Hz sensor in a marine environment. The recording and control electronics may also be mounted in a pressure vessel for protecting the recording and control electronics in a marine environment. The battery may be suitably sealed for use in a marine environment.

The non-magnetic pressure vessel in which the Hz sensor is mounted is further mounted within a sleeve fixedly secured to the base to shield the Hz sensor from water currents in a marine environment.

The recording and control electronics and power supply may be mounted within a housing supported by the support. The Hz sensor may also be secured to the housing.

The Hz sensor may be releasably secured to the base by a releasable securing means acting between the housing and the base.

The housing may further include floatation means for causing the housing and the Hz sensor to float upon release from the base.

The housing may include retrieval aids for assisting in retrieval of the housing subsequent to its release.

The sleeve may be fixedly secured to the housing and the releasable securing means may act directly between the sleeve and the housing.

The retrieval aid is at least one member selected from the group consisting of a flag, a radio transmitter, a flashing light and a strayline with float.

The release mechanism may be activated by either or both of a timer and a signal receptor.

### DESCRIPTION OF DRAWINGS

Preferred embodiments of the invention are described in detail below with reference to the accompanying illustrations in which:

FIG. 1 is a resistivity model in cross-section of a hydrocarbon-charged offshore geological structure;

FIG. 2 is a model similar to FIG. 1 of the Troll Field Reservoir used for modelling and calculations by the inventors in the present case;

FIGS. 3 to 6 are graphs of period (vertical axis) versus distance (horizontal axis) corresponding to FIG. 2 and showing respectively TE resistivity, TE phase, TM resistivity and TM phase;

FIG. 7 is a graph illustrating the magnitude of the vertical component Hz of the magnetic field across a resistivity boundary; the magnitude of Hz, i.e. the amplitude without respect to sign is symbolized |Hz|;

FIG. 8a is a schematic illustration of a general model of a negative resistivity structure;

FIG. 8b is a schematic illustration showing three particular models (Model 1, Model 2, and Model 3, with depth increasing with number) of the general model of FIG. 8a;

FIG. 9 corresponds to Model 3 in FIG. 8b and illustrates graphically the lateral variation of |Hz| across the deepest anomalous resistivity structure (Model 3) of FIG. 8b, for different periods of the natural EM signal;

FIG. 10 illustrates normalized in-phase induction arrows (i.e. the real portion of the induction arrow), also called “induction vector” for Model 3 of FIG. 8b for a 200 second period;

FIG. 11a is a plan view of a representative hydrocarbon-charged structure showing representative sensor locations according to the present invention;

FIG. 11b is a vertical cross-section taken along one of the sensor lines of the structure of FIG. 11a;

FIG. 12 shows a standard MT parameter called “tipper magnitude” (based on Hz) calculated from the model shown in FIG. 2; and

FIG. 13 is a schematic view of an Hz sensor system according to the present invention.

### DESCRIPTION OF PREFERRED EMBODIMENTS

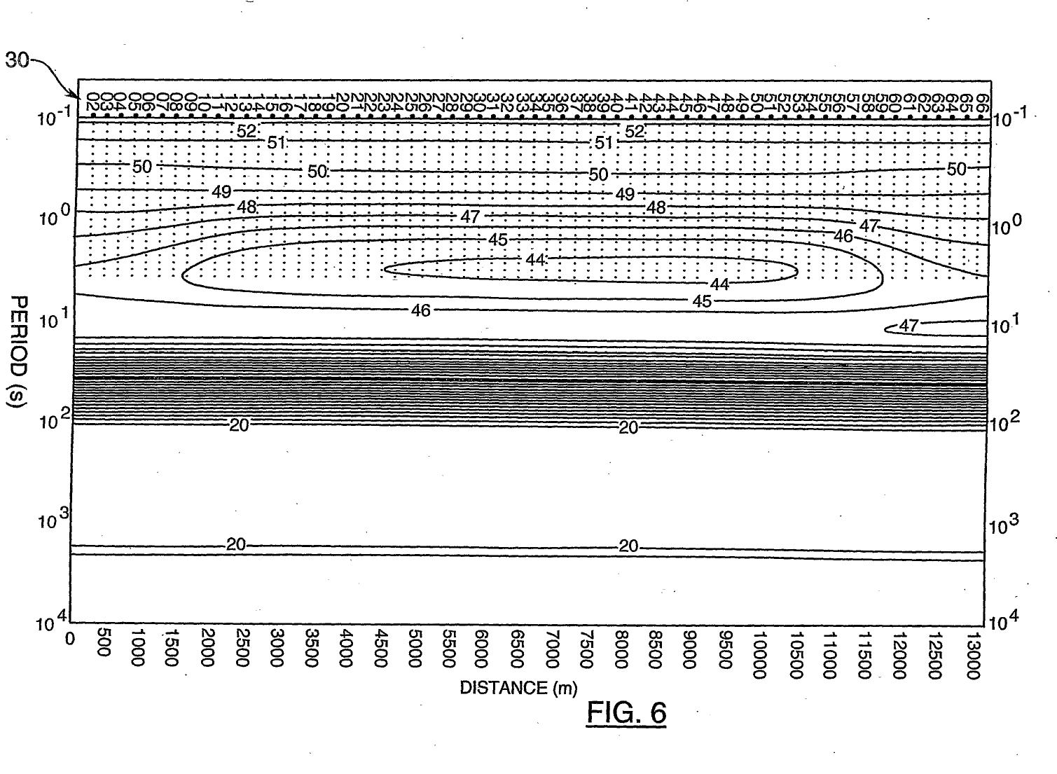

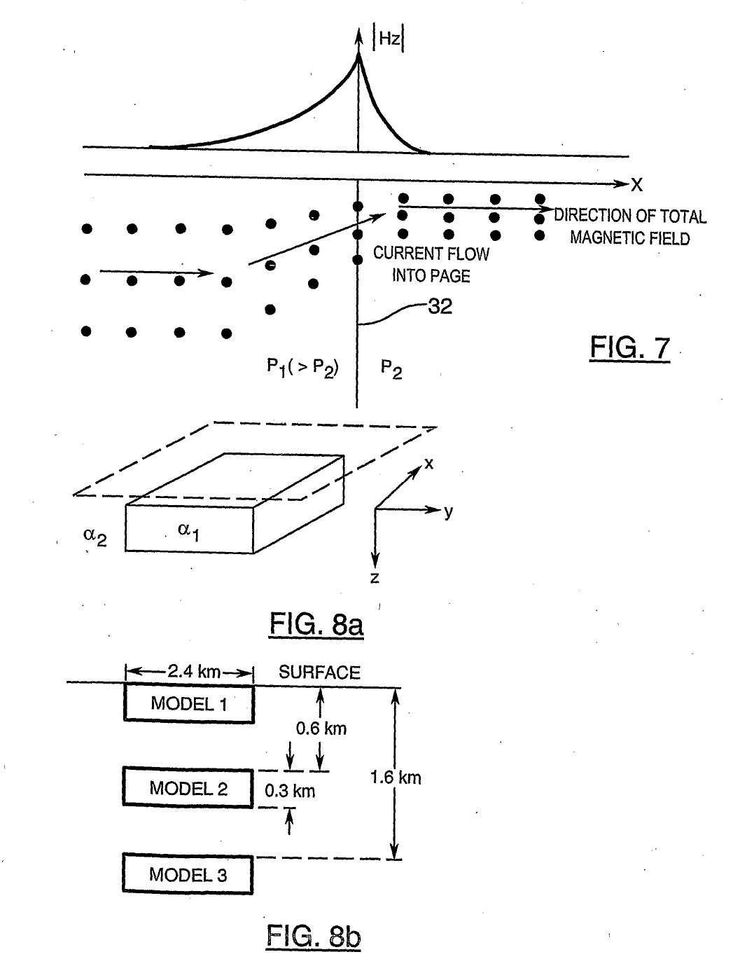

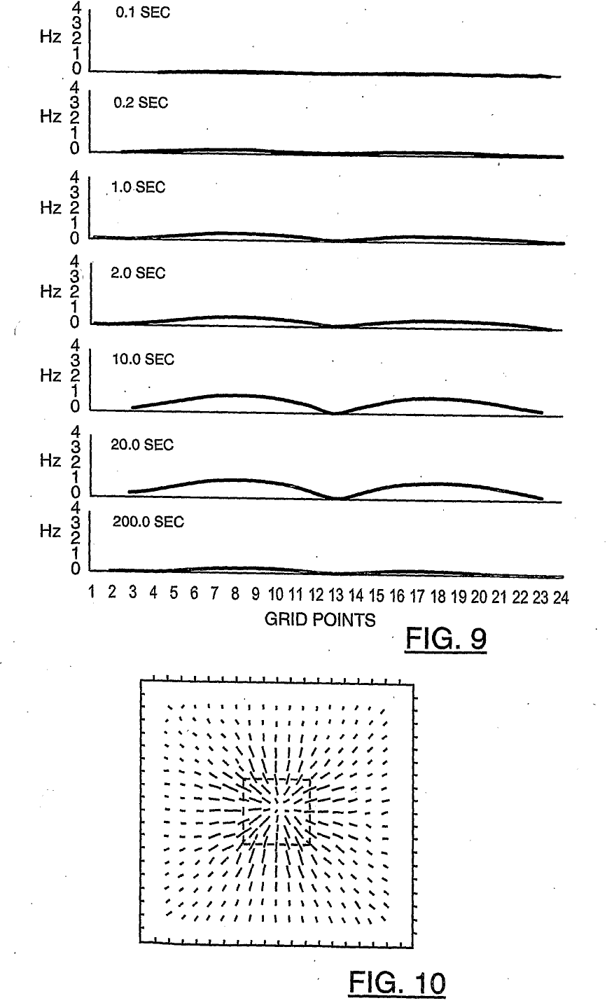

According to a first preferred embodiment of the invention, the vertical component Hz of the magnetic field arising from the natural source (as opposed to man-made or controlled source) is measured simultaneously at a plurality of points on the sea floor, suitably located with respect to the structure under investigation. It is known from the physics of the problem that, in the absence of noise, the magnitude (i.e. the amplitude without reference to sign) of the vertical component “Hz” of the magnetic field is non-zero only at or near a resistivity boundary 50, as illustrated in FIG. 7 (from McNeill et al., 1991) which shows the variation of |Hz| (vertical axis) across a resistivity boundary 32. Here, “|Hz|” is the mathematical notation denoting the magnitude of the vertical magnetic field Hz. If in FIG. 7 we imagine another such boundary some distance to the left or right, the laterally extended model then approximates that of the spatially finite offshore, hydrocarbon-charged, resistive sub-bottom structure that is the object of interest. Other similar models can be found in the published literature, with smaller resistivity contrasts typical of those in hydrocarbon exploration. FIGS. 8a and 8b from (Lam et al, 1982) shows a model of a negative resistivity structure. FIG. 9 from (Lam et al 1982) shows the lateral variation of |Hz| across the anomalous resistivity structure, for different periods of the natural EM signal.

As illustrated in FIG. 9, |Hz| shows a local maximum above such resistivity boundaries, decreases to zero far away from the boundaries, and decreases to a local minimum at the epicentre of the anomalously resistive zone lying between the two lateral boundaries. Thus, the invention foresees cost saving and data redundancy by deploying a relatively large number of Hz sensors along a suitable profile(s) crossing the subsurface seismic structure whose resistivity is to be determined. It can be appreciated that use of a single component sensor system provides a considerable operational cost and weight saving compared to use of a measurement system with multiple components. Also, since there is non-zero loss rate of instrumentation in marine deployments (of the order of 1%), minimizing the cost of the measuring device also minimizes the cost due to unavoidable losses.

As mentioned, Hz is non-zero only at or near resistivity boundaries. As a magnitude measurement, |Hz| does not take into account the “sign” (relatively positive or relatively negative, compared to background) of the resistivity contrast associated with the structure under investigation. |Hz| can be used therefore, only to indicate resisitivity boundaries, but not to infer the “sign” of the resistivity anomaly. As the discovered structure is not expected to be less resistive than its surroundings, if evidence of a resistivity contrast is observed, it can be inferred reasonably reliably to be due to a positive resistivity anomaly, even if the polarity of the anomaly is not known.

To attain unambiguous information about the sign of the anomaly, it may be possible to utilize the relative spatial variation of other properties of the spatially varying normalized Hz field (amplitude and phase), which may possibly indicate the polarity of the subsurface resistivity anomaly, in addition to indicating its boundaries as already mentioned.

Alternatively, or in addition, to determine unambiguously the polarity of the resistivity anomaly, we may utilize another standard MT parameter called the “Induction Vector” (hereafter called “IV”) which is well known to the art. The IV is a complex quantity with real and imaginary parts. The IV requires measurement of all three components of the magnetic field, that is, Hz (vertical component) and Hx and Hy (orthogonal horizontal components) at the same or nearby locations. The actual azimuths of Hx and Hy are usually not critical as long as both horizontal sensors are orthogonal, which in practice may be achieved such as by fixing them in a rigid frame. The attitude of the horizontal sensors is usually known to ±1 degree, and this is usually sufficient. Accuracy of orientation of the vertical sensor is more critical, as discussed below.

Note that the IV does not require measurement of the electric field components.

As indicated in FIG. 10 from (Lam et al 1982), in the usual plotting convention used therein, the real portion of the IV points towards negative resistivity anomalies (less resistive than surroundings) and away from positive resistivity anomalies (more resistive than the surroundings), within the frequency band which senses the anomaly.

Additional known relationships between the real and imaginary portions of the IV with respect to space (lateral position relative to a resistivity anomaly), and/or with respect to frequency, and/or with respect to time, may possibly be used to infer the presence and possibly sign of the subsurface resistivity anomaly, as well as approximate geometric information.

However, note that in all cases, accurate vertical orientation of the vertical magnetic sensor is always required. This is especially critical for the marine application where Hz is expected to be smaller, in general, than usually observed in land-based MT surveys.

The approach described herein contrasts in one sense with known techniques in that neither the MCSEM technique nor the marine MT technique is required to, or usually measures, the vertical magnetic component Hz.

As mentioned above, it has been considered that measurement with naturally occurring horizontal electric and magnetic fields alone cannot in general reliably detect a thin resistive target (the hydrocarbon structure).

However, as already mentioned, the presence of a lateral resistivity boundary creates a secondary (anomalous) field with a non-zero vertical component Hz. In the absence of such a lateral resistive boundary, this vertical component must be zero everywhere.

As indicated in FIG. 9, the spatial variation of |Hz| has a characteristic pattern around an anomalously resistive target.

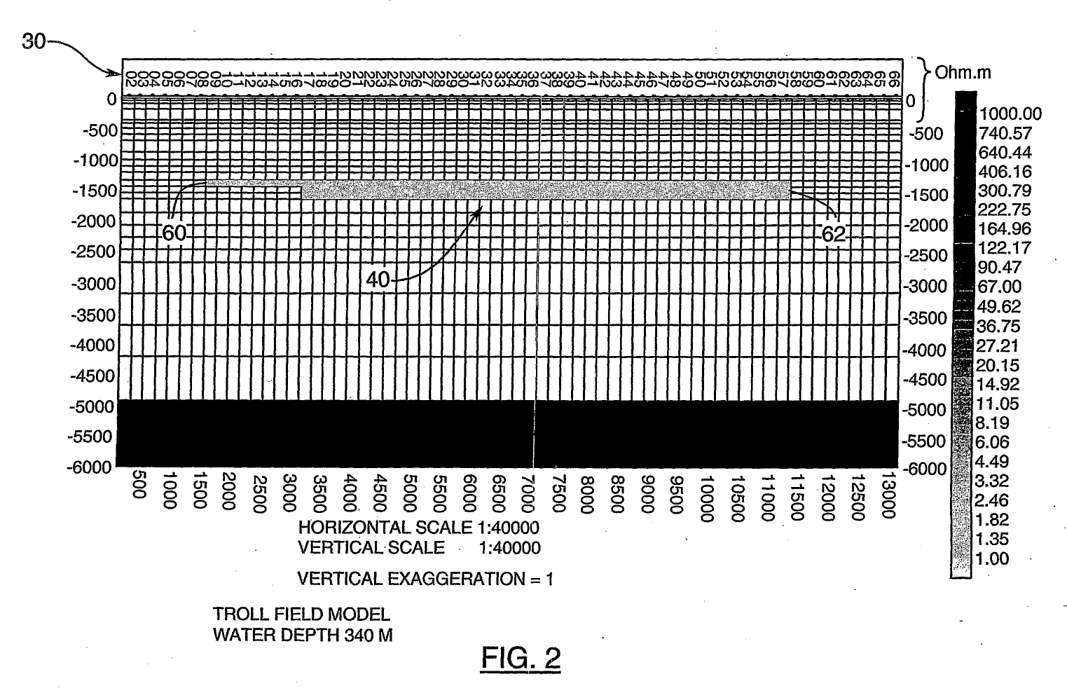

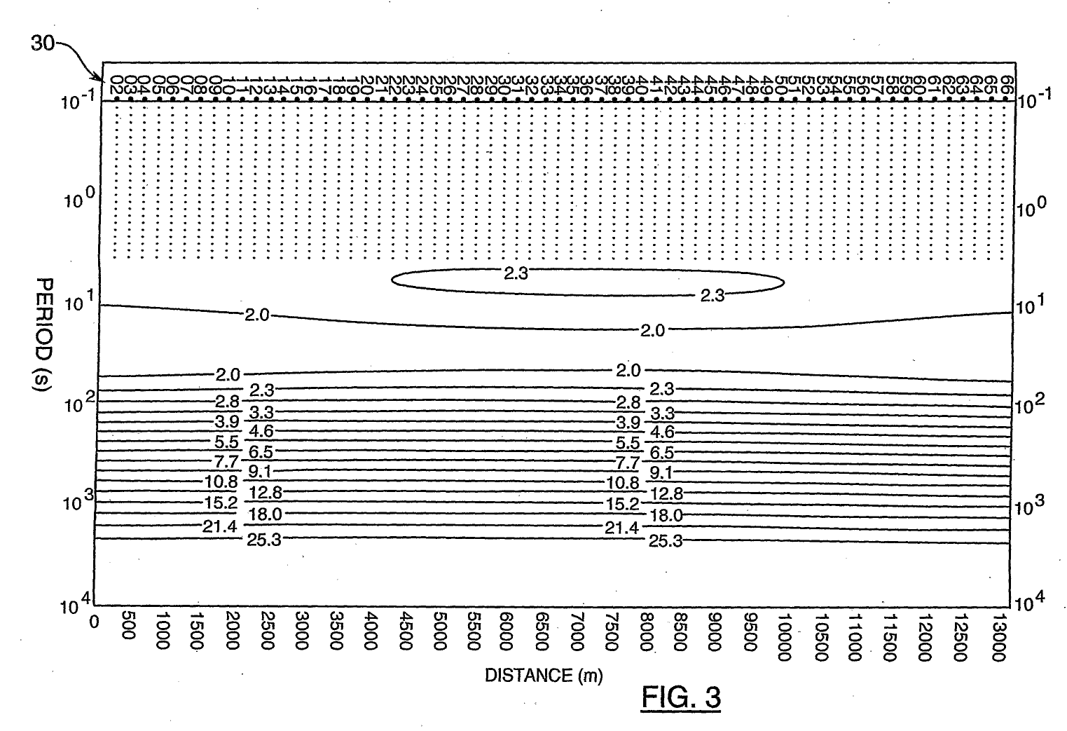

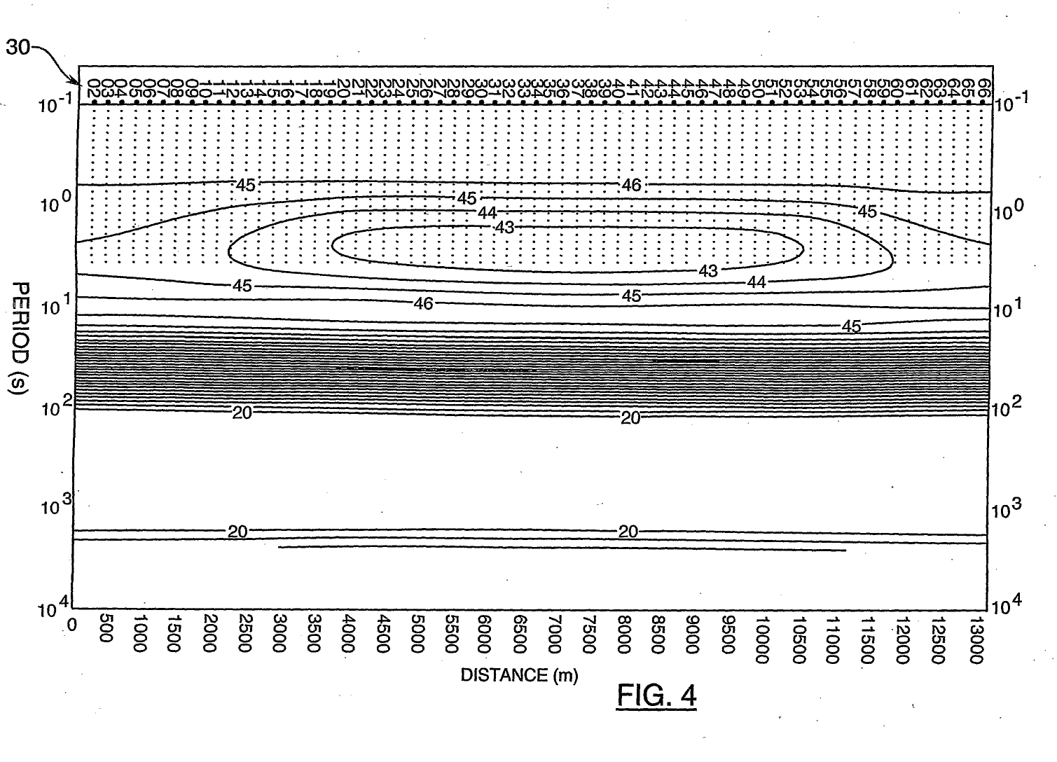

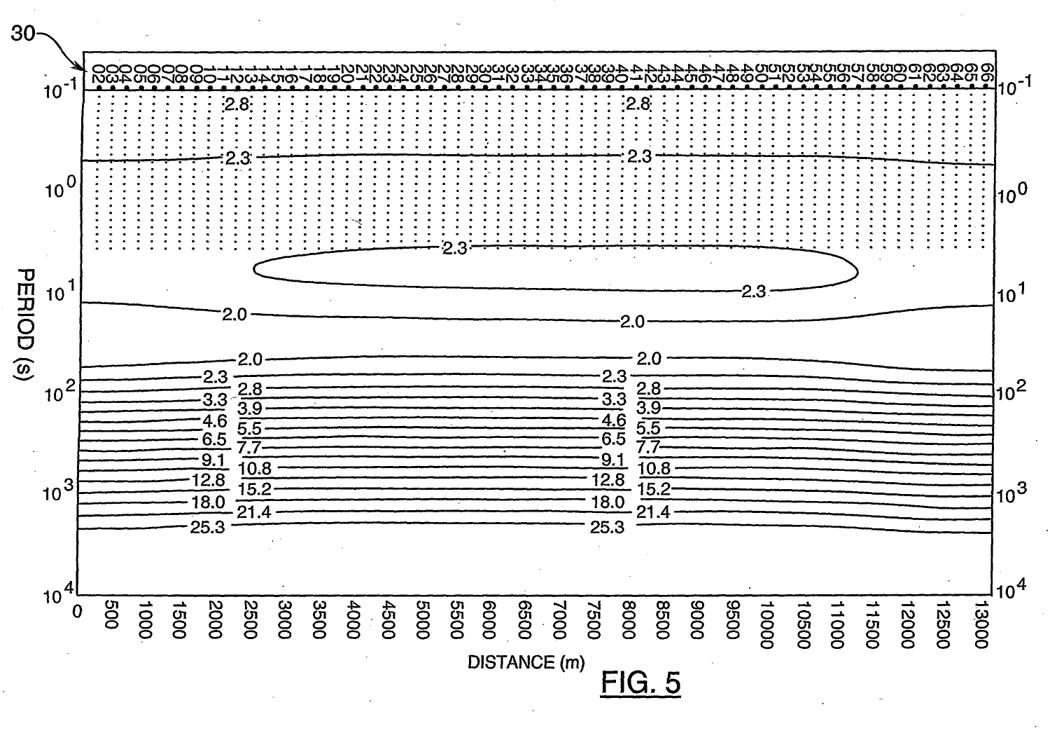

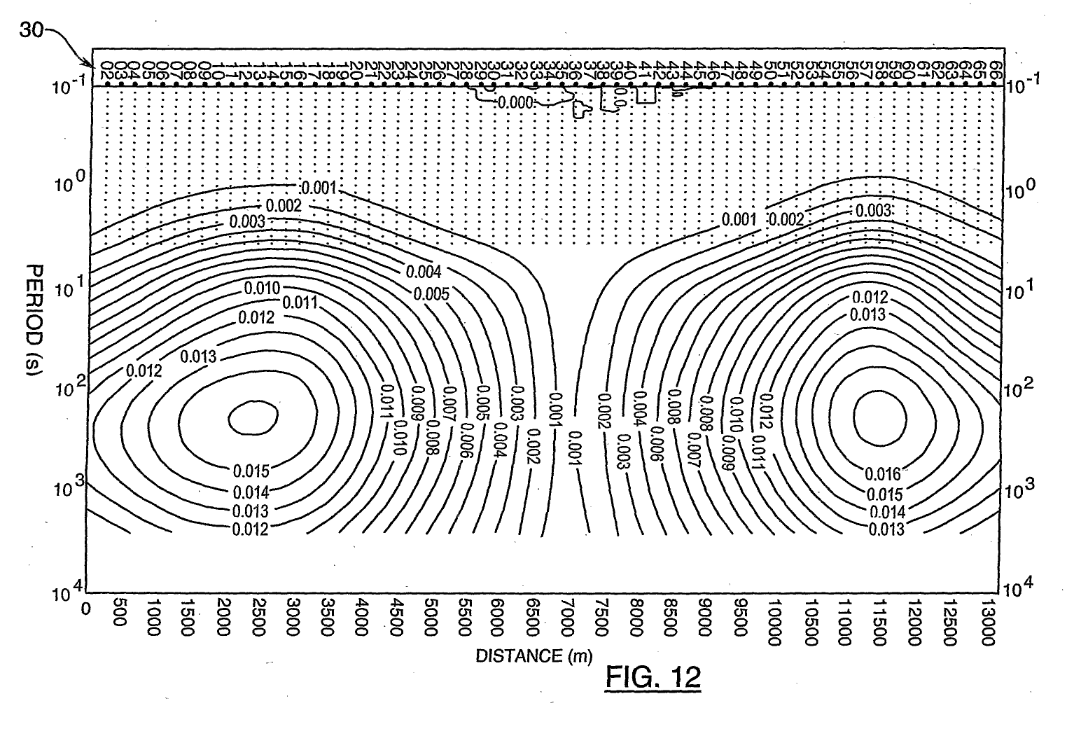

FIG. 12 shows an MT parameter called “tipper magnitude” (well known in the art) as calculated from the model shown in FIG. 2. The tipper (which is similar to, but not exactly the same as the IV) is derived by expressing the measured vertical magnetic field Hz as a linear combination of the ratios of measured Hz to the measured horizontal magnetic fields Hx and Hy. Tipper magnitude considers only amplitude, not sign. Since it is derived from Hz, it displays the same spatially varying characteristics as Hz and |Hz| when crossing an anomaly. As an aside, we note that as mentioned, Hx and Hy are usually measured at the same point as Hz, but as the rate of horizontal variation of Hx and Hy is usually small and usually less than that of Hz, it is also permissible to measure Hx and Hy at a different location from Hz, as long as the distance is not too great.

FIG. 12 shows tipper magnitudes as great as 0.017, or 1.7% of the combined horizontal fields Hx and Hy at the same location, with the maxima occurring within a specific frequency band (here centered on approx. 200 second period), and laterally coincident with edges 60, 62 of the resistive structure 40 shown in FIG. 2. It is known from onshore experience that such relatively small tipper magnitudes have been observed in onshore MT surveys, and can be, and have been, used reliably in onshore structural interpretation.

Since, as mentioned above, Hz is zero far away from lateral resistivity boundaries which give rise to Hz, so is the magnitude of the tipper, which is derived from Hz. Likewise, the magnitude of the IV (which also is derived from Hz) must be zero everywhere in the absence of any lateral resistivity contrast.

Although Hz must be zero far away from lateral resistivity boundaries, the background value against which a tipper anomaly must be identified is not zero, but some non-zero magnitude defined by the noise floor of the measurement. Noise arises from various sources; the significant sources are next discussed.

The primary field and secondary (anomalous) field arising from the hydrocarbon-charged zone are both exponentially attenuated as a function of distance by passage through sea water and sub-bottom sediments. Instrument noise floor, however, remains nearly constant at a given frequency. The ratio of the signal strength (or more precisely, spectral energy density) to the sensor noise in the same frequency band defines the sensor S/N (signal-to-noise) ratio. The expected S/N ratio when measuring Hz in the marine environment with the usual Hz sensor used for onshore measurements is in the range 0.5:1 to approx. 5:1 (depending on signal strength at the time of measurement) before any improvements that may be obtained by stacking. (Note that Gaussian random noise can be attenuated by a factor of SQRT(N) by stacking N estimates.) In other words, the sensor used for onshore MT has sufficiently low noise floor to be used for measuring Hz in the marine application.

Another known source of error is temperature variation of the sensor during the measurement. As the temperature of the medium (sea water) at the sea floor is known to be nearly constant 4 degrees C. everywhere in deep water, temperature-related variation is not a significant concern. The instruments can be calibrated at this temperature, and/or known temperature-related variation can be computed accurately and used for correction.

Another source of error is insufficiently accurate sensor calibration. This can be mitigated by the use of precision relevant components in the calibration circuits (more precise than those normally used or required for onshore MT). Note this type of error is also Gaussian and random across a group of independent sensors, or across repeated calibrations of the same sensor, so stacking the results from N sensors or N calibrations of the same sensor will reduce this type of noise by a factor of SQRT(N).

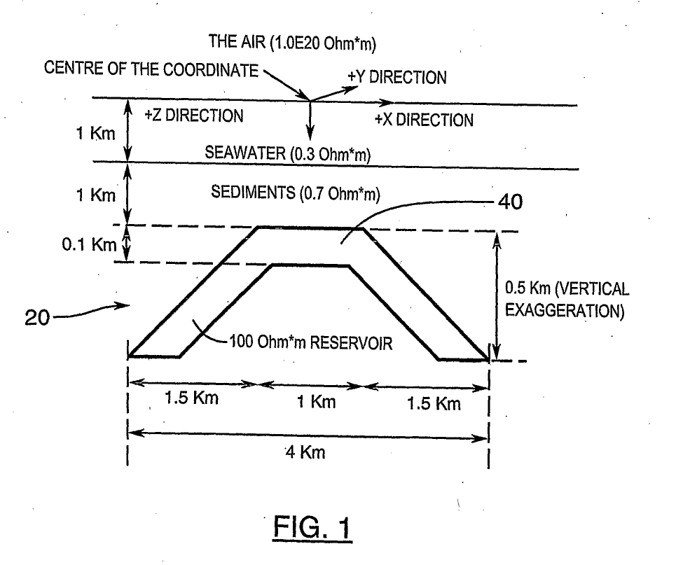

Another source of noise is non-zero seafloor slope. FIGS. 1 and 2 assume a horizontal seafloor, which is necessary to display clearly the expected anomalous response. (Farelly et al 2004) report depth variation of 17 m along the ˜20 km line. This corresponds to a seafloor slope of 0.085% or equivalently 0.05 degrees (3 minutes). It can be appreciated that a sloping seafloor constitutes a subtle (seemingly) but real macroscopic lateral resistivity boundary. The effect of a sloping seafloor is thus to create a non-zero background level of |Hz| everywhere across a measurement area, within a certain frequency band in which the slope is sensed.

This frequency band overlaps with that in which the desired anomalous signature is sought and the slope effect therefore must be understood and compensated for. The magnitude of the background noise arising from this source depends on the resistivity of sea water and sediments, seafloor slope and water depth. Since these are known, a suitable correction can be computed and applied. Note that the normalizing procedure mentioned elsewhere herein will remove the noise from this source as sensed at the reference location. The frequency dependence of noise from this source (the noise spectrum) varies somewhat with water depth; as it is not the same everywhere, normalization alone will not remove all such noise, although it can be expected to remove most of it. The magnitude of “slope noise” varies with slope, another factors being equal; a constant seafloor slope of 1 degree will produce a background noise in tipper magnitude of approximately 0.014. With a constant 1 degree seafloor slope, the change in noise background at a given frequency of interest (over a distance of 20 km) is approximately 0.001; so normalization will remove most of the this noise.

Another significant source of error in measuring the vertical magnetic field Hz is error in vertical orientation of the sensor. If the vertical sensor is not truly vertical, then it actually senses a small portion of the (much stronger) horizontal magnetic fields Hx and Hy at the measuring point. Assuming the Hz sensor, once installed on the sea floor, remains stationary in orientation (fixed in attitude) at an angle slightly less than true vertical (90 degrees), for the duration of the measurement, then it will always sense some positive error due to this reason. This type of error is always positive (“bias error”) so it cannot be significantly reduced by stacking and averaging successive (in time) estimates derived from the same sensor, or by stacking measurements across a set of such sensors.

In FIG. 12, the anomalous vertical field parameter, “Tipper Magnitude”, is approx. 1.7% (0.017) of the magnitude of the combined horizontal magnetic fields Hx and Hy. In other words, the combined horizontal fields are ˜60× greater in magnitude than the expected vertical field. A small error in vertical orientation of the Hz sensor can thus produce a large error due to unwanted contributions from the horizontal fields. The error in the Hz field measurement due to error in vertical orientation is proportional to the sine of the error angle.

Assume we wish to reliably measure tipper magnitudes (or equivalently, relative |Hz| magnitude anomalies) of approx. 0.017. Assume other sources of error have been satisfactorily reduced by stacking and averaging successive (in time) estimates derived from the same sensor, or by stacking measurements across a set of such sensors, or other procedures. Suppose we wish to have an error ceiling of approx. 0.0017 arising from vertical orientation error, or one-tenth of the magnitude of the FIG. 12 anomaly. A simple trigonometric calculation (arcsin (0.0017)) indicates that an error of 0.097 degrees (˜6 arc-minutes, or ˜1.7 milliradians) in vertical orientation will produce an error of approx. 0.0017. If the desired error floor is 0.003, the corresponding error angle limit is 0.17 degrees (10 arc minutes). For an error floor of 0.004, the error angle limit is 0.23 degrees or ˜14 arc minutes. This accuracy of vertical orientation is achievable without prohibitive effort or cost, using known available techniques and technologies such as precision tilt meters and automatic levelling devices, already (or readily) adapted to the marine environment for the application herein.

Alternatively, a new mechanism described and claimed below, may be used to ensure the required accuracy of vertical orientation.

A plurality of related Hz measurements can be made using a set of identical measurement units which incorporate a single vertically oriented magnetic sensor. A suitable sensor would be the type used for onshore survey work, adapted in known ways for the marine application. In addition to ensuring very accurate vertical orientation, the main adaptation for marine application is effected by installation of the essential components of the magnetic sensor and electronics in a suitable non-magnetic pressure vessel(s) made of, e.g. aluminium or glass. Glass may be preferred for the Hz sensor since it is non-conductive and therefore does not attenuate the magnitude of the measured Hz component, which we expect to be small. Other related adaptations are required, such as specialized marine connectors, expendable anchor (detachable on command), buoyancy members, etc. but these are known, and are or would be well within the skill of persons familiar with such systems.

The apparatus as described above, which measures only a single component of the magnetic field (Hz) is considerably smaller, simpler and much less costly than currently used apparatus. Currently used receiver apparatus weighs up to 300 kg in air (with the concrete anchor), has a larger footprint (up to 10 m with electric sensors attached), requires heavier anchors, more buoyancy members, larger battery capacity, sizeable shipboard cranes for deployment and recovery, a larger, more costly vessel, a larger crew, etc. Additional significant cost arises from the capital cost of the MCSEM controlled source equipment and its deployment during the duration of the measurement. As indicated, the MCSEM/MMT receivers are subject to a loss rate of approx. 1%. Note that the controlled source itself and/or its costly specialized tow cable (which may cost several hundred thousand dollars) are also subject to a non-zero loss rate.

Thus, with the approach described herein, significant cost savings can be realized, as previously mentioned, even while many more sensor systems are deployed in the same area or along the same line. The effort required to reliably measure the natural-field MT anomalies as described herein is compensated for by the significant decrease in cost, as well as other advantages.

Advantages of deploying more sensors simultaneously, in addition to productivity, are data redundancy and reduction of spatial aliasing.

Data redundancy means that more independent measurements are available within the area of interest, and subset(s) of these can therefore be stacked and averaged together (or otherwise processed using relevant known algorithms and procedures) to improve S/N (signal-to-noise) ratio. For example, the anomalous pattern illustrated in FIG. 12 is a 3-D pattern. There are many known 1-D, 2-D, 3-D, 4-D or even higher-dimensional pattern recognition techniques developed in other disciplines that can be utilized to identify such a pattern against a noise background, even when S/N ratio is relatively low. A second aspect of redundancy is robustness against loss of data and or/loss of equipment due to the non-zero loss rate of such bottom-installed marine sensor systems.

Spatial aliasing arises when the anomalous pattern to be measured is smaller than the spacing between the sensors, and therefore its true lateral extent may be overestimated. We know that the maxima of |Hz| occur directly above lateral resistivity boundaries; i.e., in the application herein, at the edges of the resistive hydrocarbon-charged structure.

In addition to determining the presence or absence of a positive resistive anomaly, we also wish to know the lateral location of the edge as accurately as possible, as well as local resistivity variations and this is achieved by deploying more sensors closer together, either along profiles or in 2-D networks.

The discussion above has generally considered only the magnitude of Hz that is, without consideration of its relative sign or its phase (relative to a quiet off-anomaly reference location to which all the “production” measurements are normalized). These additional properties can be extracted in a straightforward way from time series of Hz recorded at many locations simultaneously. These properties, too, are known to display characteristic relative spatial variations (for example, see (Rokityansky 1982)), and can also be analyzed to advantage in ways similar to those mentioned above for |Hz|. As can be appreciated, any of those which may display a diagnostic invariant pattern with respect to a positive sub-bottom resistive anomaly can be used to identify the polarity of the anomaly without reference to measurement of other field components.

Note that normalization as mentioned herein requires measurement at a minimum of two locations simultaneously. The instantaneous response at any given location is proportional to the instantaneous characteristics of the inducing EM field (the MT field), which is only quasi-periodic; and normalization thus removes the unpredictable temporal variations. As well, it removes the background response of the reference site and thus displays only the anomalous response in the survey area.

The fact that |Hz| has a local maximum directly above a lateral resistivity boundary offers an advantage over a known weakness of the MCSEM technique; namely, that in using MCSEM, the lateral boundaries of the resistive target may be difficult to determine and subject to error (sometimes considerable) in part due to relative locations and relative orientations of source-sensors-target.

Depth inversion is difficult with MCSEM for several reasons. These include the limited bandwidth of the source (since the technique can only operate in a narrow range of frequencies, a decade or less).

Also, it is well known to practitioners of MCSEM that the presence of additional geologic noise above the target (in the form of positive resistivity anomalies from resistive rock layers such as sills of volcanic rocks) greatly complicates the reliable interpretation of MCSEM data and may even render it unusable (Dell'Aversana, 2005).

By contrast, depth inversion in MT is well developed, and the natural EM signal is always available (at no cost) over a wide range of frequencies. Although depth inversion based on Hz alone is imprecise, nevertheless, we can improve it by exploiting the known geometry of the target under study to predict the approximate characteristics of the response expected if the structure is hydrocarbon-charged, i.e. if it exhibits a positive resistivity anomaly with respect to its surroundings.

The MT response from different resistive bodies at different depths occurs in different frequency ranges. The natural MT signal provides a very wide range of useful frequencies at the sea floor (several decades) and, given sufficient vertical separation, variation of response with frequency can be used to infer the presence of the target, and differentiate it from other resistive zones elsewhere in the geologic section. As mentioned, the expected characteristics of the anomaly can also be used to aid in this approach. The wide frequency range of the natural-field MT measurement permits and supports identification of resistive targets at different depths, which (depending on the depth and vertical separation) may manifest themselves as Hz-related and other MT anomalies in different frequency bands of the measured frequency spectrum.

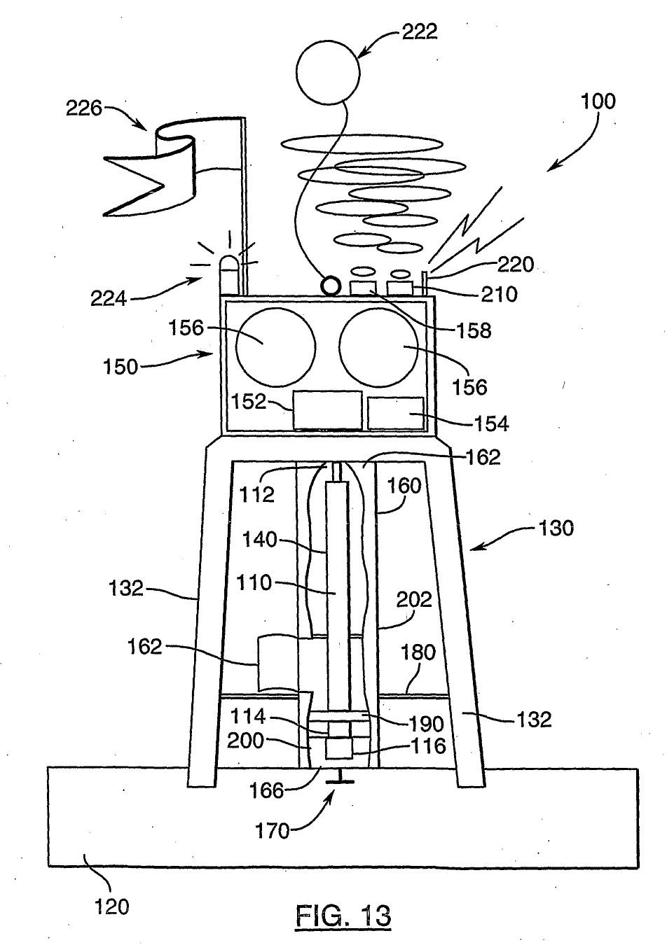

As mentioned above, precise vertical orientation of the Hz sensor is critical. This can be accomplished by use of existing technology (such as precision tilt meters, precision active levelling devices). However, to reduce cost, it would be desirable to have an alternative mechanism to ensure precise vertical orientation of the Hz sensor. FIG. 13 illustrates a sensor apparatus 100 utilizing a simple and effective method of passively and automatically orienting Hz sensor 110 by using the earth's gravitational field.

The sensor apparatus 100 has an expendable base or anchor 120 of any suitable non-magnetic material, such as concrete or other suitable non-magnetic material as is commonly used in similar oceanographic instrumentation. The base 120 supports a support leg assembly 130 which may be of plastic (or other non-magnetic material). The support leg assembly 130 may have a plurality of legs 132 (typically at least 3 for stability) and supports both an Hz sensor 110 and an associated componentry housing generally indicated by reference 150.

The housing 150 may be supported above the legs 132 as illustrated. An open ended tubular sleeve 160 is shown extending downwardly from the housing 150 toward the base 120. The Hz sensor 110 is mounted within a pressure vessel 140 which in turn is mounted within the sleeve 160 so as to be protected by the sleeve 160 from any currents which might otherwise cause the Hz sensor 110 to sway from the vertical.

The Hz sensor 110 is swingably mounted at a top end 112 thereof in a manner which enables it to sway freely in the manner of a pendulum. The Hz sensor 110 is further provided with a weight 116 at a bottom end 114 thereof opposite the top end 112.

The sleeve 160 and the housing 150 may be secured to the base 120 by a release mechanism 170 (discussed in more detail further below) which acts between the base 120 and the sleeve 160. The support leg assembly 130 may be secured to the base 120 to remain with the base upon release of the sleeve 160 and housing 150.

Optionally the support leg assembly 130 may release with the sleeve 160 and housing 150.

Stabilizer arms 180 may be provided between the legs 132 of the support leg assembly 130 and the sleeve 160 to further stabilize the sleeve 160. The sleeve 160 may be provided with an access panel 162 for allowing access to the Hz sensor 110. A tilt meter/precision levelling mechanism 190 may optionally be provided between the Hz sensor and the sleeve 160 however this adds expense and complexity and accordingly would only be desired in applications where it is believed that the pendulum based system described in more detail below may not prove effective.

The housing 150 may house a pressure vessel containing recording and control electronics 152, and a battery 154 for powering the electronics. Buoyancy spheres 156 may be provided to cause the housing 150 and Hz sensor 110 to float toward the surface upon release from the base 120.

An acoustic pinger 158 may be mounted to the housing 150 to assist in mapping the location of the apparatus 100 upon deployment. Retrieval aids such as a radio beacon 220, a strayline with float 222, a flashing light 224 and a flag 226 may be mounted to the housing 150. The radio beacon 220 and flashing light 224 would typically be configured to be in operation only in a recovery mode so as not to interfere with the Hz sensor during sensing and to conserve battery power.

The Hz sensor assembly 100 is manufactured and suspended in such a way as to permit it to hang precisely vertically under the force of gravity, absent any disturbing forces. Thus, even if the base 120 of the entire apparatus 100 is not truly horizontal on the sea floor (which will be the usual case), the Hz sensor portion is nevertheless always constrained to hang vertically within a very small angular error, without any active levelling or compensation. The Hz sensor portion of the apparatus as described thus comprises a classical damped pendulum, in which the sensor apparatus 110 is the “arm” and the weight 116 at the bottom 114 of the vertical sensor 110 is the pendulum “bob”. It is well known that such a pendulum is dynamically stable against small deviations from true verticality caused by external forces. Any such deviation will cause the pendulum to swing from side to side (or “oscillate”) with a period proportional only to its length and the acceleration due to gravity at the pendulum's specific location. The weight of the pendulum bob does not affect the frequency of oscillation and does not add a weight penalty to the total required weight of the apparatus, which in any case must be sufficient to “fix” it to the sea floor sufficiently well to resist lateral forces and vertical (buoyancy) force. Note that the sea water inside the sleeve 160 provides viscous damping of any oscillations of the Hz sensor “pendulum” 110 about true verticality that, for example, might be caused by varying horizontal forces caused by varying ocean currents.

As mentioned above, the vertical sensor is also shielded from direct motion of bottom waters by a sleeve 160 as illustrated in FIG. 13. The sleeve 160 may simply be a plastic pipe of somewhat larger diameter than the Hz sensor pressure vessel 140. The sleeve 110 is open at a top 164 and a bottom 166 to permit seawater to enter. Note that if the entire apparatus does not come to rest perfectly horizontally on the sea floor (which will be the usual case), the Hz sensor, when hanging vertically under the force of gravity, will not be parallel to the side walls of the sleeve 160. Thus the sleeve 160 must be somewhat greater in diameter than the pressure vessel 140 acting as the Hz sensor 110 container—enough to permit the Hz sensor to hang vertically without contacting the walls of the sleeve 160, when the apparatus 100 is at rest on the sea floor.

It may be desirable to stabilize the Hz assembly 110 within the sleeve 160 during descent (to prevent it from swinging from side to side and contacting the sleeve walls). A simple means of stabilizing the sensor 110 in the sleeve 160 is to open the access door in the sleeve 160 just prior to deployment in the sea, and to install an “ice bushing” 200 of appropriate dimensions as a “collar” around the Hz sensor. It will be appreciated that dividing the ice bushing 200 into two or more parts makes it easy to install around the pressure vessel which contains the Hz sensor 110. The ice bushing 200 would typically be in the form of a hollow cylinder with appropriate inner and outer diameters. As the descent rate of apparatus 100 is of the order of 0.5 m/sec, it will quickly sink below the thermocline and remain in waters with a temperature of approx. +4 deg C. until the recovery sequence is initiated. The ice bushing 200 will melt slowly, and once melted, the Hz sensor 110 will be free to hang vertically under the force of gravity. A flange 202 may be provided on the inside of the sleeve 160 to limit upward floating of the ice bushing 200.

Another “optional” item is an acoustic receiver or transponder system 210. Existing MCSEM/MMT receivers incorporate such systems, which are relatively costly. The usual procedure is as follows. When it is considered that the duration of acquisition is sufficient, and may be ended, the survey vessel is positioned within transmission range of the device to be retrieved, then sends a coded acoustic “release” signal which is received by the acoustic receiver or transponder system mounted on the seafloor apparatus. Upon receipt of the release signal, the seafloor apparatus initiates a “burn sequence” which results in release of the anchor after approx. 15-30 minutes. This type of anchor release mechanism (“burnwire system”) is well known to the art.

In order to reduce cost, the present invention foresees (optionally) dispensing with the receiver portion of the acoustic system, and initiating the release sequence at a certain pre-programmed time. Since the expected duration of seafloor deployment is of the order of 24 h to 48 h, and since the weather can be reasonably predicted that far in advance, it is not expected that this approach will result in significant logistic or cost penalties.

The first embodiment described above considers principally or only an array of Hz sensors. The motivation for using for the most part, or only, Hz sensors has been described: this approach provides logistic simplicity and very significant cost saving.

The calculation of an Induction Vector (“IV”) (which in the western plotting convention, points toward conductors, away from resistors) requires measurement of 2 orthogonal horizontal components of the magnetic field at or near the same location where the vertical component Hz is measured; if few in number, the 2-component stations would preferably be positioned to either side of the subbottom seismic structure under investigation.

In this invention, the intrinsic properties of the MT EM field in relation to resistive or conductive targets are exploited to answer key questions cost-effectively, including: does the target display a resistivity contrast with its surroundings? If so, what is the sign of the anomaly? What are its lateral boundaries? What is its inverted depth?

The invention provides several advantages, including but not limited to logistic simplicity; reduced cost; and better definition of the target's lateral boundaries. The anomalies observable with this invention are comparable in magnitude to, or perhaps even larger than, those observed with the MCSEM technique. The invention permits, but does not require, a multiple-pass methodology, with each pass using equipment optimized for that pass. These passes may be combined or permuted in any suitable and economically advantageous way.

Pass 1 utilizes a plurality of Hz measurements as described above to determine if the subsurface target displays a resistivity contrast with its surroundings. Since the target is not expected to be significantly less resistive than the background rocks (only more resistive, i.e. hydrocarbon charged), the mere presence of |Hz| (magnitude) anomalies can be used to infer with reasonable reliability the presence of a positive resistivity anomaly as well as its lateral boundaries, and secondarily to determine rough variations of resistivity within the general outlines of the target. As mentioned elsewhere, the spatial variations of relative (normalized) Hz phase and the sign of the variations may in addition unambiguously determine the sign of the resistivity anomaly.

Pass 2 adds ≧1 set of Hx and Hy measurements (made at or near one of the Hz measuring locations) to permit unambiguous calculation of the induction vector(s) and thus of the sign of the resistivity anomaly. This pass provides a more detailed view of the conductivity variations within and around the target. The lateral sensitivity of this measurement permits the target to be sensed at some distance laterally from the measurement point. Mapping a field of IVs removes the spatial imprecision inherent in this lateral sensitivity and provides a spatial pattern that is usually easy for the human observer to visualize and interpret. More subtle patterns with lower S/N ratio can be extracted by pattern recognition techniques referred to elsewhere.

Note that measurements made of only the magnetic field are free of the well-known MT “static shift” effect, and (at the frequencies of interest) are also insensitive to small scale topographic variations of the sea floor. Variations due to sea floor topography would be measured at much higher frequencies than those due to deeper, sub-bottom anomalies. In deep water, the primary field at those high frequencies may be below the system noise floor. Correction for seafloor slope has been mentioned above.

Pass 3 uses equipment that measures (in addition to Hx, Hy, and Hz) two horizontal (Ex, Ey) components of the electric field. This permits resistivity calculations and resistivity vs. depth inversions and can be used to develop 1-D, 2-D and 3-D models of the sub-bottom resistivity structure.

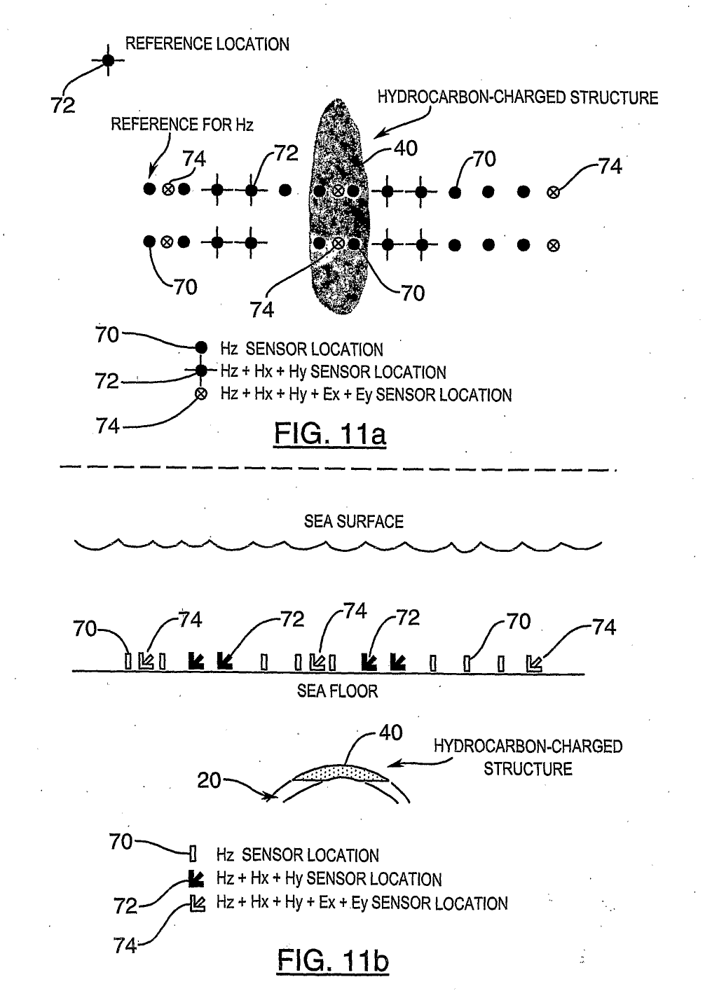

In order to optimize costs, in using the three-pass arrangement described above, three types of sensors may be deployed. The use of three types of sensors is illustrated in FIGS. 11a and 11b which respectively show in plan and in vertical cross-section a typical sensor deployment. Toward the centre of the illustrations is a hydrocarbon charged layer 40 within a hydrocarbon charged structure 20. The sensor deployment includes Hz only sensors 70, Hz+Hx+Hy sensors 72 and Hz+Hx+Hy+Ex+Ey sensors 74. The sensors 70, 72 and 74 are deployed in two parallel lines across the hydrocarbon charged layer 40. Other deployment patterns may be used. A remote Hz+Hx+Hy sensor 72 is placed in a reference location away from the hydrocarbon charged layer 40.

It will be noted that the bulk of the sensor locations utilize only Hz sensors 70 which, as discussed above, are the least expensive of the three types of sensors. Fewer Hz+Hx+Hy sensors 72 are utilized and still fewer Hz+Hx+Hy+Ex+Ey sensors 74 are utilized.

It can be appreciated that the hydrocarbon-charged structure, once discovered, and if economic, will be put into production. Production essentially means withdrawing as much as possible of the hydrocarbons in the structure, at some optimal rate. The withdrawn hydrocarbons are replaced by formation brines (having the same resistivity as background rocks) and/or by injected sea-water and/or by injected formation water produced along with the hydrocarbons. Obviously, the production process will therefore change the lateral and vertical resistivity boundaries of the hydrocarbon-charged zone—the so-called “oil-water” or “gas-water” contacts. The hydrocarbons are lighter than water, and so, during production, the lower contact between hydrocarbons and formation waters moves upward. As well, the lateral boundaries of the hydrocarbons move towards the producing wells and towards the topographically highest part of the structure.

It can be appreciated, therefore, that an additional embodiment of the present invention relates to installation of permanent or quasi-permanent sensor arrays at the sea floor (possibly with vertical sensors emplaced in holes drilled into the sea floor) in order to monitor the evolution of the sub-bottom resistivity structure of a hydrocarbon-charged structure during the production process. Such geophysical measurements are referred to as “time-lapse” or “4-D” measurements, comprising the usual three spatial dimensions x-y-z, and in which the fourth dimension is time. The main technique used in 4-D hydrocarbon reservoir monitoring is the 3-D seismic technique; such repeated seismic surveys in the marine environment may cost on the order of millions of dollars, and the seismic technique as noted elsewhere may not be sufficiently sensitive to the oil/water contact.

In such permanent arrays installed over producing reservoirs, each apparatus need not be operationally autonomous. The producing wells are always linked to the semi-permanent sea-surface installation (such as an FPSO, or Floating Production, Storage and Offloading vessel) by conduits for the produced hydrocarbons, as well as by cables for transmission of electric power to the sea floor assemblies and for two-way transmission of data and/or commands. In such configurations, the sea floor MT sensor array can, without any significant cost or logistic penalty, likewise be physically linked to the sea-surface installation, to receive power from the surface, and for two-way communication of data and/or commands.

The above description is intended in an illustrative rather than a restrictive sense, as variations may be apparent to those skilled in the relevant arts without departing from the scope of the invention as defined by the claims set out below. For example, although the invention is described above principally in terms of application to offshore exploration, it may also be adapted for use in onshore exploration. Furthermore, the sensor arrangement and the multi-pass methodology may be adapted to or be used in conjunction with controlled source measurements.

### REFERENCES

(Dell'Aversana, P. 2005) “The importance of using geometrical constraints in marine controlled source electromagnetic data inversion”, Poster No. EMP1.3 presented at SEG 75th Annual Meeting, Houston, Tex., USA.
(Eidesmo, T. et al., 2002) “Sea Bed Logging (SBL), a new method for remote and direct identification of hydrocarbon filled layers in deep water areas” First Break Magazine, Vol. 20, March 2002, pp. 144-152.
(Eidesmo, T. et al., 2003) U.S. Pat. No. 6,628,119 B1 issued Sep. 30, 2003
(Farrelly, B. et al., 2004) “Remote characterization of hydrocarbon filled reservoirs at the Troll Field by Sea Bed Logging”, presented at EAGE Fall Research Workshop, Rhodes, Greece, 19-23 Sep., 2004.
(Gamble, T. et al., 1979) “Magnetotellurics with a remote reference”, GEOPHYSICS Vol. 44, pp. 53-68, 1979.
(Lam, H. et al., 1982) “The response of perturbation and induction-arrows to a three-dimensional buried anomaly” GEOPHYSICS Vol. 47 No. 1 p. 51-59, January 1982.
(McNeill et al., 1991) “Geological Mapping using VLF Radio Fields” in Investigations in Geophysics. No. 3, Electromagnetic Methods in Applied Geophysics, Vol. 2, Application, Parts A and B, ed. Nabighian, M. published by Society of Exploration Geophysicists, Tulsa, Okla., USA, 1991.
(Rokityansky, I., 1982) “Geoelectromagnetic Investigation of the Earth's crust and mantle”, 381 p, ISBN 3-540-10630-8, Springer-Verlag, Berlin, 1982.
(Um et al., 2005) “On the marine time-domain controlled source electromagnetic method for detecting hydrocarbon reservoirs”, paper EM3.5, presented at SEG 75^{th} Annual Meeting, Houston, Tex., USA, November, 2005.

1. A method for determining whether an offshore bottom geological structure, of which the approximate geometry and location are known, exhibits a resistivity contrast with surrounding rocks, a positive contrast being interpreted as due to the presence of hydrocarbons in the structure; the method comprising:
measuring the vertical component (Hz) of the magnetotelluric (MT) field simultaneously at a plurality of places on the sea floor, along at least one profile across the geological structure, to determine which of said places have anomalously contrasting |Hz| indicating a boundary of an anomaly across which there is a lateral resistivity-contrast;
inferring the sign of the resistivity contrast, absent the expectation of a negative resistivity contrast.

2. A method for determining whether an off-shore bottom geological structure, of which the approximate geometry and location are known, exhibits a resistivity contrast with surrounding rocks, a positive contrast being interpreted as due to the presence of hydrocarbons in the structure; the method comprising:
measuring the vertical component (Hz) of the magnetotelluric (MT) field simultaneously at a plurality of places on the sea floor, along at least one profile across the geological structure, to determine which of said places anomalously contrasting |Hz| indicating a boundary of an anomaly across which there is a lateral resistivity contrast;
normalizing the Hz measurements against an off anomaly reference location and determining the sign of the contrast from spatial variation of the sign and phase of the normalized Hz field.

3. A method for determining whether an off-shore bottom geological structure, of which the approximate geometry and location are known, exhibits a resistivity contrast with surrounding rocks, a positive contrast being interpreted as due to the presence of hydrocarbons in the structure; the method comprising:
measuring the vertical component (Hz) of the magnetotelluric (MT) field simultaneously at a plurality of places on the sea floor, along at least one profile across the geological structure, to determine which of said places have anomalously contrasting |Hz| indicating a boundary of an anomaly across which there is a lateral resistivity contrast;
measuring horizontal components (Hx, Hy) of the magnetotelluric field on the sea floor at a minimum of one location adjacent the structure at or nearby one of the Hz measuring locations, and from this, determining the sign of the resistivity anomaly.

4. The method of claim 3 wherein:
said determination is made by one of calculating an induction vector field from the horizontal and vertical measurements (Hz, Hy, Hz) and calculating a the tipper, tipper magnitude, induction vector real and imaginary components.

5. The method of claim 4 further comprising:
measuring two orthogonal horizontal electronic components (Ex, Ey) of the magnetotelluric field at said places to provide data for resistivity calculations and resistivity vs. depth inversions.

6. The method of claim 1 wherein:
said measurements of said magnetotelluric field components are recorded using a recording apparatus associated with a sensor deployed by being allowed to sink to the sea floor and retrieved through floating to the surface by activation of a floatation apparatus connected to said recording apparatus.

7. The method of claim 1 wherein:
said measurements are made by sensor arrays at said sea floor which are at least quasi-permanently installed and linked to a semi-permanent sea-surface installation to receive power therefrom and for communication therewith.

8. The method of claim 7 wherein:
said sensor arrays include sensors emplaced in holes drilled into the sea floor.

9. An Hz sensor apparatus comprising:
a base;
a support extending upwardly from said base for swingably supporting an Hz sensor to hang downwardly in a pendulum like manner in a deployed configuration;
recording and control electronics mounted to said base and communicating with said Hz sensor; and
a power source connected to said recording and control electronics for providing power thereto.

10. The Hz sensor apparatus of claim 9 wherein:
said Hz sensor is mounted in a non-magnetic pressure vessel for protecting said Hz sensor in a marine environment;
said recording and control electronics are mounted in a pressure vessel for protecting said recording and control electronics in a marine environment; and,
said battery is suitably sealed for use in a marine environment.

11. The Hz sensor apparatus of claim 10 wherein:
said non-magnetic pressure vessel in which said Hz sensor is mounted is further mounted within a sleeve fixedly secured to said base to shield said Hz sensor from water currents in said marine environment.

12. The Hz sensor apparatus of claim 11 wherein:
said recording and control electronics and said power supply are mounted within a housing supported by said support; and,
said Hz sensor is secured to said housing.

13. The Hz sensor apparatus of claim 12 wherein:
said Hz sensor is releasably secured to said base by a releasable securing means acting between said housing and said base.

14. The Hz sensor apparatus of claim 13 wherein:
said housing further comprises floatation means for causing said housing and said Hz sensor to float upon release from said base.

15. The Hz sensor apparatus of claim 14 wherein:
said housing includes at least one retrieval aid for assisting in retrieval of said housing at sea surface subsequent to its release.

16. The Hz sensor apparatus of claim 14 wherein:
said sleeve is fixedly secured to said housing; and,
said releasable securing means acts directly between said sleeve and said housing.

17. The Hz sensor apparatus of claim 15 wherein:
said retrieval said is at least one member selected from the group consisting of a flag, a radio transmitter, a flashing light and a strayline with float.

18. The Hz sensor apparatus of claim 16 wherein:
said release mechanism is activated by one of a timer and a signal receptor.

19. A method for temporarily stabilizing a movable member within a sleeve during deployment, said method comprising placing an ice bushing about said movable member extending between said movable member and said sleeve.

20. The method of claim 19 wherein said ice bushing is made up of segments to assist in placement.
